(19) United States
(12) Patent Application Publication
(10) Pub. No.: US 2013/0032825 A1
(43) Pub. Date: Feb. 7, 2013

(54) Resonant Optical Cavity Semiconductor Light Emitting Device

(71) Applicant: John Gilmary Wasserbauer, Castro Valley, CA (US)

(72) Inventor: John Gilmary Wasserbauer, Castro Valley, CA (US)

(21) Appl. No.: 13/223,144

(22) Filed: Aug. 31, 2011

Related U.S. Application Data
(60) Provisional application No. 61/378,791, filed on Aug. 31, 2010.

(51) Int. Cl. H01L 33/60

(52) U.S. Cl. 257/88; 257/98; 257/E33.06

(57) ABSTRACT

The present invention is a light emitting device apparatus and method of fabrication. The structure employs a waveguide in the lateral (x) direction formed via materials index, resonant wavelength and/or current-induced index changes. In the vertical (y) direction a resonant optical cavity is formed via distributed Bragg reflector and/or metal mirrors with sufficient reflectivity so as to create a substantial standing wave. The light is thereby constricted to propagate in the longitudinal (z) direction. A tapered output section may be employed to suppress lasing in the longitudinal direction or to losslessly transfer the light from the confined section to a resonant output coupler. Conversely, feedback may be employed to induce lasing in the longitudinal direction by suitable means, such as a periodic variation in the material index, resonant wavelength, gain or loss. The resonant output coupler may be formed by suitable means, such as mirror or cavity modulation.

This application claims the priority date of provisional application No. 61/378,791, filed 31 Aug. 2010, the contents of which are incorporated herein by reference.

### BACKGROUND OF THE INVENTION

1. Field of the Invention

The present invention relates to designs, systems and methods of a semiconductor light emitting diode or a semiconductor laser.

2. Description of the Related Art

The resonant optical cavity (ROC) has proven very useful in controlling and manipulating light in various forms of optical devices. An optical cavity with a high quality factor, or Q is a required element in the formation of a laser, for example. The ROCs for semiconductor lasers typically comprise a distributed Bragg reflector (DBR) for a vertically-emitting laser or a phase-shifted distributed feedback (DFB) grating for an edge-emitting laser. In light emitting diodes, a ROC is sometimes used to improve the vertical emission and/or narrow the emission spectrum. In most of these devices, however, the ROC is formed in only one dimension, with optical confinement in the other dimensions provided by some type of waveguide. One exception to this rule is the photonic bandgap approach, where a two-dimensional lattice of holes provides the feedback and a missing hole, or defect, forms the cavity. Nevertheless, the limitations of the current approaches preclude the realization of a vertically-emitting device with a large single mode or high-power sub-threshold emission. The present invention provides means for simultaneous feedback in the vertical and longitudinal directions so as to create ROCs in each dimension and enable lasing in both. This enables the realization of scalable, high-power, single- or multi-mode vertically emitting semiconductor lasers. Conversely, if amplification of spontaneous emission is desired, lasing may be suppressed by means of a tapered optical output coupler in the longitudinal direction. This enables the realization of scalable, high-power light-emitting diodes, while retaining the advantages of a controllable, narrow emission spectrum and efficient vertical light extraction.

High power semiconductor lasers are used in a variety of commercially significant applications, including diode pumped solid state (DPSS) lasers, erbium doped fiber amplifiers (EDFAs), sensing, laser range finding, free space communications, data communications, laser machining and directed energy systems, among others. In general, the desired characteristics of the laser are high power, single spectral mode output and high efficiency. Vertically emitting lasers can provide excellent efficiency and single mode output and are not subject to catastrophic optical damage (COD). Currently, however, they cannot simultaneously produce high power. Furthermore, arrays of VCLs are not easily coupled for this purpose. Edge-emitting lasers, on the other hand, can easily produce high power at reasonable efficiencies. However, they tend to struggle when it comes to high power single mode control and also are subject to COD. What is needed is a high power, vertically emitting design with scalable, lateral mode control.

High brightness semiconductor light emitting diodes (LEDs) are primarily used in lighting applications, although a multitude of other applications exists, such as displays, signaling, sensing, and data communications. In general, the desired characteristics of the LED are high power, high efficiency and a fixed peak wavelength. In addition, low thermal impedance and low manufacturing costs are significant requirements. To date, progress in the realization of HBLEDs has been limited by a combination of high current efficiency droop, low extraction efficiency, poor thermal dissipation, and high manufacturing costs. Most LEDs exhibit a significant drop in efficiency at high operating current. The two leading theories ascribe this to hot carrier and Auger effects. A satisfactory solution to these problems has yet to be found. The low extraction efficiency results from the large difference between the indexes of refraction of the compound semiconductor, typically GaN, used to generate the light (>3) and air (1) leading to a high degree of total internal reflection. The most popular remedies for this include patterned substrates [1] or bottom mirrors, which reflect the light upward, and surface roughening [2], which randomizes the angle of incidence and increases the probability of photon extraction. In practical devices these methods leave room for improvement. Various methods are used to improve the thermal conductance of the LED structure, but most involve growing the epitaxial layers on, or moving them to, a high thermal conductivity substrate, such as silicon carbide (SiC), silicon (Si), or copper (Cu). Few device-level approaches are aimed directly at addressing this issue. Finally, the high cost of manufacturing is tied to the high cost and/or small size of the substrates on which the semiconductor layers are grown. The most popular substrates, sapphire and SiC, are small and expensive, respectively. A device technology that could be implemented on Si, or make use of high-quality lateral epitaxially overgrown (LEO) material, would have potentially great cost and performance advantages, respectively. An even greater manufacturing cost is the low color yield due to the non-uniformity of the quantum wells in the active layers. This forces manufacturers to sort or “bin” the LEDs according to wavelength. What is needed is a method of post-epitaxial wavelength control.

In light of these issues, a different approach is warranted, one in which the primary direction of light amplification is a combination of lateral and vertical, in which the wavelength is controlled, and in which light extraction is efficient and vertical. The potential advantages of the invention disclosed herein include higher single mode power, higher photon extraction efficiency, greater wavelength control, more efficient heat extraction, greater reliability, and lower cost. We will now describe the ROCSLED structure in detail showing how each of the above advantages may be achieved.

### SUMMARY OF INVENTION

The present invention is a light emitting diode or laser diode apparatus and method of fabrication. The structure employs a waveguide in the lateral (x) direction formed via materials index, resonant wavelength and/or current-induced index changes. In the vertical (y) direction a resonant optical cavity is formed via distributed Bragg reflector and/or metal mirrors with sufficient reflectivity so as to create a substantial standing wave. The light is thereby constricted to propagate in the longitudinal (z) direction. A tapered output section, also in the longitudinal direction, is employed to losslessly transfer the light from the confined section to the resonant output coupler. Wavelength selectivity may also be formed in the longitudinal direction by suitable means, such as a periodic variation in material index, resonant wavelength, gain or loss. A resonant output coupler may be formed by suitable means, such as mirror and/or cavity modulation. In this way, light may be confined to a narrow range of wavelengths (below-threshold) or a single wavelength (above threshold) in all three dimensions post-epitaxially. For both LED and lasers the peak emission wavelength may be determined. In operation, light is conditioned within the resonant optical cavity to be efficiently extracted by the resonant output coupler.

### BRIEF DESCRIPTION OF THE DRAWINGS

In the drawings, like numerals describe like components throughout the several views:

FIG. 1. Perspective view of a ROCSLED structure. Note that horizontal features are not to scale. The surrogate substrate to which the RCSLED is bonded has been omitted for clarity.

FIG. 2. Vertical cross section (section A-A of FIG. 1) and optical mode profiles of a ROCSLED.

FIG. 3. Lateral cross section (section B-B of FIG. 1) of a ridge-etched ROCSLED waveguide.

FIG. 4. Lateral cross section of a ridge-etched, oxide-aperture ROCSLED waveguide.

FIG. 5. Lateral cross section of a ridge-etched, resonant wavelength modulated ROCSLED waveguide.

FIG. 6. Longitudinal cross section showing generic, periodic material index variation.

FIG. 7. Longitudinal cross section showing periodic resonant wavelength modulation.

FIG. 8. Longitudinal cross section showing index modulation via alternating mirror/waveguide structure.

FIG. 9. Longitudinal cross section showing index modulation via alternating semiconductor/dielectric mirror structure.

FIG. 10. Perspective view showing periodic waveguide width variation.

FIG. 11. Longitudinal cross section showing a periodic grating etched into the quantum wells.

FIG. 12. Longitudinal cross section showing a periodic blocking implant in the quantum wells.

FIG. 13. Longitudinal cross section showing an asymmetric device with feedback and output coupler.

FIG. 14. Longitudinal cross section showing a symmetric device with feedback and output coupler.

FIG. 15. Top view of circular ROCSLED with multiple, tapered output couplers (starburst pattern).

FIG. 16. Top view of circular ROCSLED with radial feedback and cavity/output coupler.

FIG. 17. Top view showing a 1-D array of tapered output coupled devices.

FIG. 18. Perspective view showing a 2-D array of tapered output coupled devices.

FIG. 19. Top view showing a 2-D array of intra-longitudinal cavity output coupled devices.

FIG. 20. Schematic cross section of the thermal gradients of (a) a large area heat source, and (b) several small line heat sources.

### DETAILED DESCRIPTION OF THE EMBODIMENTS

In the following detailed description, reference is made to the accompanying drawings, which form a part hereof, and in which is shown by way of illustration specific embodiments in which the invention can be practiced. These embodiments are described in sufficient detail to enable those skilled in the art to practice the invention, and it is to be understood that other embodiments can be utilized and that structural changes can be made without departing from the spirit and scope of the present invention. Therefore, the following detailed description is not to be taken in a limiting sense, and the scope of the present invention is defined by the appended claims. In addition, throughout this specification the term “emission wavelength” shall be understood to mean a narrow range of wavelengths around a central peak, the width of which depends on the specific layer thicknesses used in the quantum wells and barriers as well as the presence or absence of one or more microcavities.

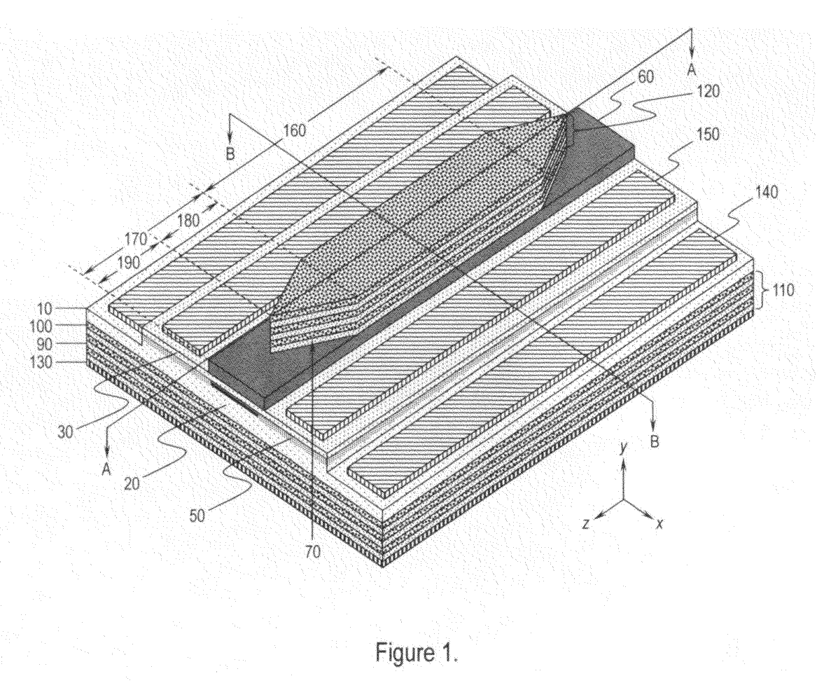

We begin with a ROCSLED structure intended for amplification of spontaneous emission. An exemplary embodiment of this structure is illustrated in FIG. 1. Throughout this specification we will use the terms lateral, vertical and longitudinal to refer to the x, y, and z directions, respectively. The Figure represents a unit cell of a two-dimensional array of ROCSLEDs that have been epitaxially transferred to a surrogate substrate (omitted for clarity), such as Si or Cu. In the vertical direction the materials stack looks much like a conventional resonant cavity light emitting diode (RCLED), whereas in the lateral direction a waveguide 160 is formed, much like that of a standard superluminescent light emitting diode (SLED) device. There are similarities and differences, however, between conventional SLEDs and the ROCSLED. As in a SLED device, spontaneous emission is amplified as it travels along the waveguide. Unlike most SLED devices, however, the waveguide of the ROCSLED contains neither absorber regions nor facets. Instead, an output coupler 170 consisting of a tapered section 180 and an output section 190 is located at each end of the waveguide. The output couplers serve to suppress lasing along the axis of the waveguide and to redirect the light vertically out of the waveguide.

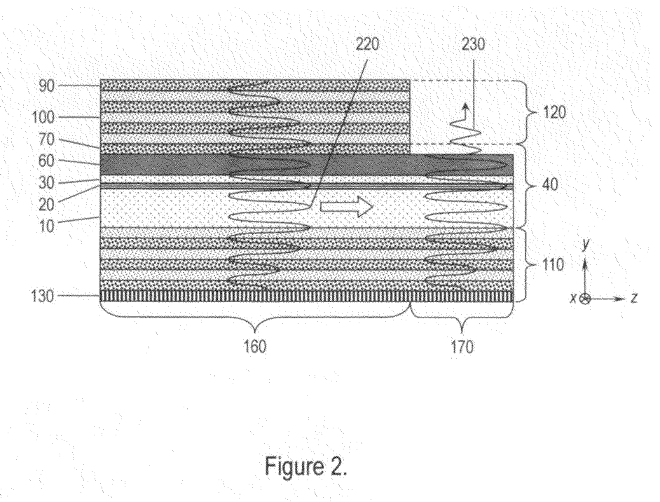

Likewise, there are similarities and differences between RCLEDs and the ROCSLED. FIG. 2 shows a vertical cross section taken along the waveguide axis. Like a RCLED, a microcavity is formed between two mirrors. In the present embodiment, the upper mirror 120 consists of a distributed Bragg reflector (DBR) formed by alternating layers of titanium dioxide (TiO₂) 90 and silicon dioxide (SiO₂) 100, whereas the lower mirror 110 comprises the same with the addition of a silver (Ag) layer 130 at the bottom for increased reflectivity and for bonding to the Si substrate. Unlike most RCLEDs, the 2-λ cavity 40 is formed from a hybrid of InGaN/GaN and dielectric materials. The InGaN/GaN layers comprise the n-layer 10, multi-quantum well (MQW) active area 20, and p-layer 30. The dielectric materials comprise a ½-λ SiNₓ layer 60 and a ¼-λ TiO₂ layer 70. The incorporation of dielectric mirrors in this embodiment necessitates the use of intra-cavity contacts 140, 150. For this reason the n-layer 10 contains an extra half wavelength of thickness. An intracavity contact can be formed by 1) a semiconductor layer that is contacted on the side, 2) a thin intracavity metal, such as Ag, placed at a node of the optical standing wave, 3) a transparent intracavity conductor, such as indium tin oxide (ITO), or a combination thereof. Side contacted devices rely on lateral current flow to achieve uniform injection and are simple to fabricate. Intracavity contacted devices have the advantage of vertical current injection, but are more difficult to achieve without adversely affecting device performance in other ways, such as adding optical loss. In an alternative embodiment, one or both DBRs could be composed of semiconductor material, such as alternating layers of AlGaN/GaN. The advantage of such layers is that they could be pumped vertically and uniformly, with the disadvantage being increased epitaxial complexity and cost.

In operation the ROCSLED works like a combination of RCLED and SLED. Referring to FIG. 2, current is injected into the active area 20 from the n− 10 and p− 30 layers and light is generated isotropically in the quantum wells. Due to the microcavity effect [3], the light is preferentially concentrated in the vertical direction setting up a standing wave 220, as it does in a RCLED. Unlike a RCLED, however, light is not extracted solely through the upper mirror. This allows the upper mirror to be designed with much higher reflectivity thereby increasing the photon recycling effect, defined here as a reduction of top-emitted light relative to longitudinally guided light. At the same time, a significant amount of spontaneous emission is launched into the laterally guided modes. This light gets amplified as it travels down the waveguide 160, as it does in a SLED. The ROCSLED, however, has a unique output coupler 170. An upper portion of the waveguide, including the dielectric mirror 120 above the cavity 40 and one dielectric layer 70 of the cavity, is removed leaving a bottom mirror 110 and a partial cavity. This partial cavity has a high reflectivity mirror 110 on the bottom side and an anti-reflective coating 60 on the top side, efficiently coupling light vertically out of the waveguide as the mode propagates longitudinally. Note that extracting the light in such a way requires the presence of a standing wave 220 in the vertical direction. Only then is a node centered on the interface between the dielectric and air at the output coupler 170, allowing photons 230 to escape without being reflected. The primary function of the resonant cavity, therefore, is to condition the light to be extracted by the output coupler. Between the waveguide and the output coupler is a transition region (FIG. 1, 180) in which the width of the upper mirror 120 and cavity dielectric layer 70 are tapered in width along the z-axis. This allows lossless transformation of the waveguide mode to the super-leaky mode, producing very low reflectivity back into the waveguide, as is required for SLED operation.

As mentioned above, the microcavity of the vertical direction serves to narrow the spontaneous emission band and produce a standing wave in the vertical direction [3]. The standing wave nodes and antinodes 220 are displayed in FIG. 2. The quantum wells are centered on an antinode producing an enhancement in the spontaneous emission [4]. Additional quantum well clusters can be placed at adjacent antinodes, and the cavity extended, to provide additional vertical gain and/or temperature stability. In the waveguide section, bottom 110 and top 120 mirrors are designed to match the electroluminescence wavelength of the MQWs and provide sufficient reflectivity so as to narrow the spectral output. The figure of merit is the cavity quality factor, Q, defined as the ratio of energy stored to energy dissipated per cycle or round trip. Typically this value is greater than 100.

In the RCLED and SLED it is necessary to provide optical confinement and wavelength selectivity in one and two dimensions, respectively. In the ROCSLED these quantities are necessary in two or three dimensions, depending on the degree of wavelength control desired. Various approaches can be utilized to create optical confinement and/or wavelength selectivity in any given dimension, with the approaches generally falling into two broad categories: modulation of gain and/or loss, and index modulation. In gain/loss modulation, the imaginary part of the refractive index is tailored so as to provide more gain or less loss for one optical mode relative to other optical modes. Index modulation techniques, by contrast, tailor the real part of the refractive index so as to form a waveguide or to provide feedback for one optical mode relative to other optical modes. Examples of the above will now be given for each of the three dimensions of the ROCSLED structure.

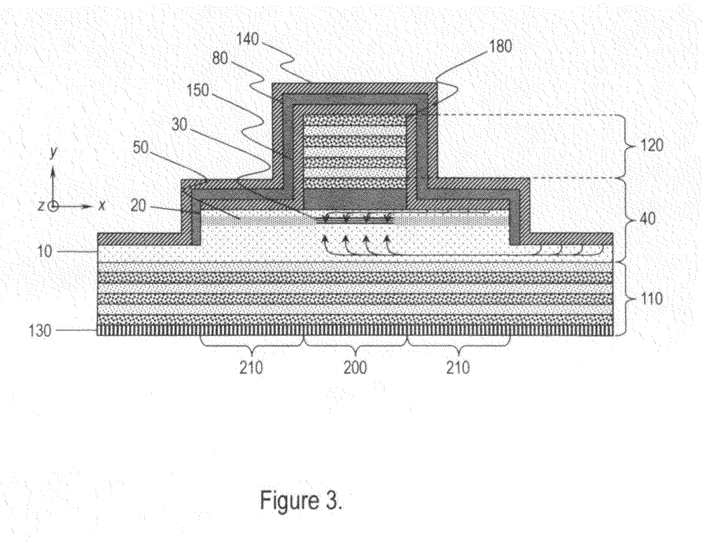

In the ROCSLED structure a waveguide is used to provide optical confinement and wavelength selectivity in the x direction. The simplest conceptual form of a waveguide is a homogeneous region of high material index, n_{core}, surrounded by a homogeneous region of low material index, n_{cladding}. Most practical forms of a waveguide comprise non-homogeneous materials and are characterized by an effective index, n_{eff}. With respect to the ROCSLED structure, the simplest practical form of a waveguide is illustrated in FIG. 3 and comprises a ridge 180 with sidewalls. The core of the waveguide consists of all the vertical layers of the ROCSLED and has an effective index, n_{core}. The cladding consists of the bottom mirror 110, the partial cavity 40, and one or more of the following: air, semiconductor, dielectric and metal layers. It has effective index n_{cladding}<n_{core}. In the embodiment of FIG. 3, the cladding includes the metal p-contact layer 150.

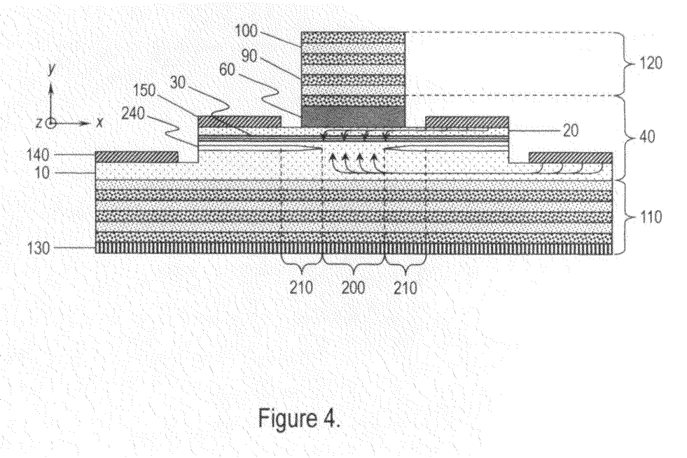

In an alternative embodiment, illustrated in FIG. 4, the waveguide may be formed by etching and oxidation of intermediate semiconductor layers to form an aperture 240. In this method, a highly oxidizable layer, such as AlN, is grown into the semiconductor portion of the structure, preferably near the active area 20. A dry or wet etch is used to expose the edge of this layer by removing the p− 30 and MQW 20 layers, and part of the n-layer 10. The wafer is placed in an oxidizing environment and the MN layer 240 is oxidized from the edge inward. The oxide layer has an index of refraction, typically around 1.5, that is much lower than that of the surrounding material, typically greater than 3. Therefore, the effective index of the oxidized portion of the waveguide is lower than that of the unoxidized portion, forming a cladding layer 210 surrounding a core 200. Advantageously, the oxidized layer comprises an injected current aperture that is self-aligned with the optical aperture, providing maximum overlap between the lateral carrier and optical profiles.

In an alternative embodiment, index contrast may be provided by a variation in the resonant wavelength of the vertical optical cavity. Throughout this specification we will refer to this as resonant wavelength or effective index modulation. This structure is equivalent to a buried rib waveguide as is known in the art. When the wave equation is separable into horizontal and vertical solutions, Hadley [5] showed that, for the vertical mode,

$$\frac{Δ {n}_{eff}}{{n}_{eff}} = \frac{Δ λ}{λ} \qquad Equation 1$$

where n_{eff} is the vertical effective index and A, is the vertical resonant wavelength. For a waveguide Δn_{eff} refers to the effective index step from the core to the cladding and is given as Δn_{eff}=n_{cladding}−n_{core}. Similarly Δλ=λ_{cladding}−Δ_{core}. Thus, by modifying the wavelength of the vertical cavity in the lateral direction, it is possible to create an effective index difference between the core and cladding sections. The sign of the effective index step can be negative, which produces a waveguide, or positive, which produces an antiguide. From Equation 1 only 1-2 nm of wavelength difference is sufficient to form the waveguide. This can be achieved by creating a thin step (1.5-3 nm) near the active area, or a thicker one farther from the active area. The step thickness required to achieve a given index difference can be calculated numerically through the effective index approximation and Equation 1.

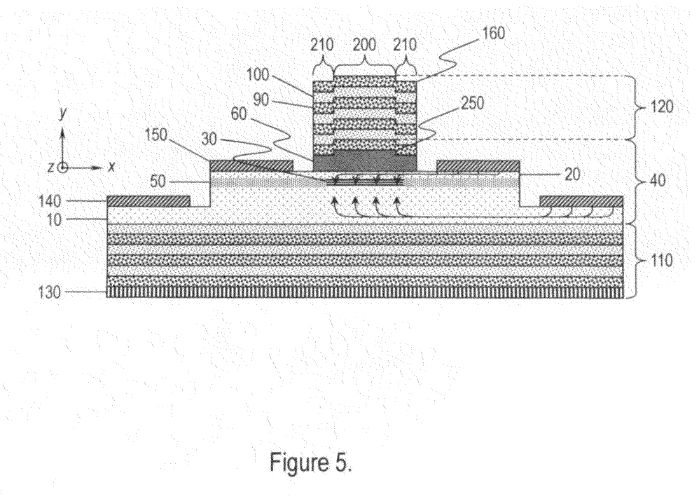

An exemplary embodiment of the effective index modulation technique is illustrated in FIG. 5, which shows an end view cross section of a ridge waveguide. This structure is equivalent to that of FIG. 3 with the addition of a buried rib 250 in the first dielectric layer 60 of the hybrid cavity 40. (Note that some metal from the contact layers 140, 150 and the dielectric isolation layer 80 have been omitted for clarity.) The buried rib can be formed by a two-step deposition of the first hybrid cavity dielectric layer 60. First, a partial SiNₓ layer thickness is disposed and patterned in the shape of the core 200 of the waveguide. A second, uniform layer is disposed and patterned in the shape of the waveguide cladding 210. The width of the cladding layer is chosen to be wider than the core 200 by an amount sufficient to contain the lateral evanescent wave. The second hybrid cavity dielectric layer 70 and top mirror layers 120 are disposed atop the waveguide. Since the hybrid cavity 40 is thinner in the cladding than the core, the resonant wavelength of the vertical structure will also be smaller. Then, by Equation 1, it follows that the effective index of the core will be larger than that of the cladding, thereby creating a waveguide.

In an alternative embodiment, a waveguide may be formed by thermally-induced index contrast. In this method, the injected current is constricted by some means, such as an ion-implant, to flow only in the core of the waveguide. The resistive heating of the injected current raises the temperature of the core relative to that of the cladding. As a result, the index of the core rises slightly with respect to the cladding, thereby forming a waveguide. In general, thermally induced index contrast plays a role in all directly injected optoelectronic devices. Furthermore, the amount of index contrast is dependent on the injected current. For single-mode lasers, for example, this can be problematic as too much index contrast can give rise to unwanted higher order modes. In the case of the ROCSLED, however, this is of less consequence for several reasons. First, LEDs are inherently broadband devices and a spread spectrum of wavelengths is tolerable. It is the peak wavelength of that spectrum that is of concern for manufacturing purposes. Second, if higher order modes do appear in the lateral dimension of the waveguide, they affect the peak wavelength and spectrum in a negligible fashion. An example of wavelength selection and sensitivity is given later.

In the y direction optical confinement and wavelength selectivity are provided by the upper and lower mirrors. The mirrors may be formed from semiconductor layers, dielectric layers, metal layers, or a combination thereof as is known in the art. In the embodiment of FIG. 3, the bottom 110 and top 120 mirrors comprise dielectric and metal layers. Advantageously, the metal layer 130 of the bottom mirror may be used as a bonding layer during epitaxial transfer. In an alternative embodiment, one or both mirrors comprise AlₓGa₁₋ₓN/GaN pairs where higher Al content (x) yields higher index contrast. Advantageously, semiconductor mirrors may be doped to allow uniform current injection through the mirror itself. Disadvantageously, high aluminum content (x≧0.3) results in a large lattice mismatch between AlGaN and GaN causing poor morphology and in-plane relaxation or cracking [6]. On the other hand, low aluminum content mirrors suffer from low contrast and require many more mirror pairs to achieve the same reflectivity, adding to the expense and complexity of the epitaxial growth. In an alternative embodiment, one or both mirrors comprise a metal layer, such as Ag (reflectivity 99%). Advantageously, metal mirrors are both electrically and thermally conductive, potentially providing both uniform current injection and good thermal heat sinking. Disadvantageously, metal mirrors are optically lossy, potentially lowering the efficiency of the LED. The tradeoffs of the above approaches can best be made by one skilled in the art, typically with the aid of numerical optical, electrical and thermal design software.

Optical confinement and wavelength selectivity in the x and y directions of the ROCSLED structure are sufficient for the basic functioning of the ROCSLED and, together with a tapered output section, provide most of the advantages thereof. In terms of wavelength control, as the gain of the cavity in increased the present embodiment will emit closer to the vertical cavity wavelength and the spectral width will narrow. Furthermore, if the quantum wells are non-uniform within an epitaxial wafer, the peak emission wavelength can be controlled lithographically during post-epitaxial processing. This control may be used to improve the color yield of LED wafers.

The ROCSLED structure presents the opportunity for additional wavelength control which may be achieved by adding optical feedback to the z-axis. With optical feedback present in all three dimensions, the cavity wavelength is uniquely prescribed and only one optical frequency is selected from the gain spectrum. By adding this feedback, lasing may be induced simultaneously in two or three dimensions. This enables the realization of scalable, high-power, single mode devices and arrays of coupled single mode devices.

A resonant optical cavity may be formed in the longitudinal direction by suitable means, such as a periodic variation in material index, effective index, or gain/loss, or any combination thereof. A periodic variation in index provides distributed feedback (DFB) along the axis of propagation. Typically this feedback takes the form of a ¼-λ grating which provides a reflection at every ½-λ peak in the standing wave. A ¼-λ shift in the grating, typically placed at its center and composed of the higher index material, is used to create a ½-λ optical cavity and select one of the two grating modes. The optical cavity can be any integral number, m, of half wavelengths. However, additional wavelengths can propagate if m>1.

The peak emission wavelength, λ, is determined by the resonant wavelength of the light along the three axes of the laser and is given by the wave number, k, according to

k²=kₓ²+K_{y}²+k_{z}², Equation 2

where k=2π/λ. If the structure is radially symmetric, the equation becomes,

k²=k_{y}²+2Kᵣ², Equation 3

where kᵣ=kₓ=k_{z}. In an exemplary embodiment of the ROCSLED, the wavelength in the x direction is determined by the waveguide, in the y direction by the optical cavity and DBR mirrors, and in the z direction by the optical cavity and DFB grating. Note that the overall emission wavelength is determined largely by the shortest wavelength in the structure, which is usually λ_{y}.

Equation 2 may be used to calculate the layer thicknesses for the vertical cavity and DBRs. Note that the minimum feature size for the periodic variation along the z-axis is ¼-λ_{z}. For example, assume that an emission wavelength of approximately 510 nm is desired, and that we wish to maintain an in-plane (lithographic) feature size of ≧1 μm. The DFB grating will then comprise ¼Λ=½Λ=1 μm segments of high and low index, where Λ is the longitudinal wavelength and ½Λ=the grating pitch. The lateral waveguide is chosen to be 10 μm wide for uniform pumping purposes. The fundamental lateral waveguide mode represents approximately ¼ of the full lateral wavelength. Thus, the lateral wavelength is approximately 40 μm. From Equation 2 the vertical optical cavity length is calculated as

$$\begin{matrix}{λ}_{y} = {( \frac{1}{{510}^{2}} - \frac{1}{{4000}^{2}} - \frac{1}{{40000}^{2}} )}^{- 1 / 2} \\ = 514.2 nm .\end{matrix} \qquad Equation 4$$

Note that the light will be traveling in a direction slightly off axis from vertical. The angle from normal can be calculated from

$$\begin{matrix}θ = {tan}^{- 1} ( \frac{{k}_{z}}{{k}_{y}} ) \\ = {tan}^{- 1} ( \frac{510 / 3.4}{4000} ) \\ = 2.1 ° .\end{matrix} \qquad Equation 5$$

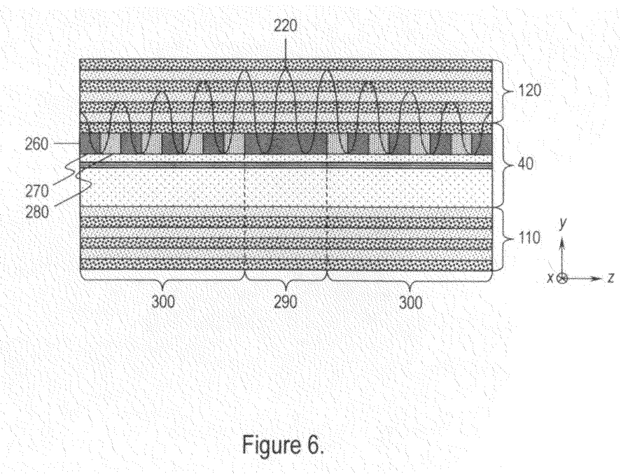

FIG. 6 displays a cross section of a generic ROCSLED with an intracavity layer 260 containing a periodic variation along the z-axis. In a purely index modulated structure, the material index of refraction is varied periodically along the z-axis by suitable means, such as etch and regrowth of a semiconductor layer, etch and redeposition of one or more dielectric layers, or implant or diffusion of a semiconductor layer. In the example of FIG. 6, layers 270 and 280 have different indexes of refraction, with n₂₇₀>n₂₈₀. In general, more than one vertical layer may be used simultaneously to achieve the desired index modulation, usually at the expense of increased process complexity. In this embodiment, the grating 300 surrounds a 1-Λ longitudinal cavity 290. The resulting optical standing wave 220 has its peak intensity at the cavity and decays with distance from the cavity.

In an alternative embodiment, a periodic variation in the index is formed via an oxide aperture within the cavity. In this method, an oxidizable layer is grown into the semiconductor portion of the structure, as illustrated in FIG. 4. A dry or wet etch is used to expose the edge of this layer and the edge is patterned or masked with the periodic structure. The wafer is placed in an oxidizing environment and the layer is oxidized from the edge inward. The oxide layer has an index of approximately 1.5, which is much lower than that of the surrounding material. Therefore, the effective index of the oxidized portion of the waveguide is lower than that of the unoxidized portion, and a periodic variation in index is realized. Advantageously, the oxide layer constricts the current periodically along the longitudinal axis, thereby reducing the required current injection for a given optical output by reducing the amount of active area that is electrically pumped.

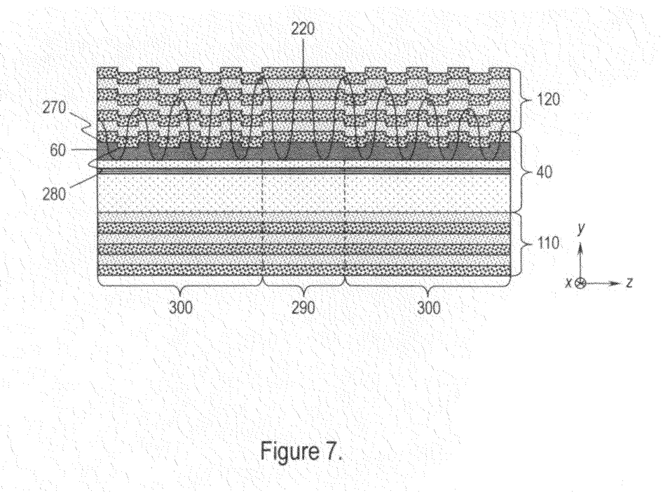

In an exemplary embodiment, depicted in FIG. 7, the effective index is varied along the z-axis by resonant wavelength modulation, as described previously. The strongest modulation can be achieved by varying the thickness of the vertical optical cavity 40 directly. In the present embodiment the thickness of the first dielectric layer of the hybrid cavity 60 is varied in the longitudinal direction. The same two-step deposition process applied to the device of FIG. 5 may be used to create high 270 and low 280 index segments to form the longitudinal optical cavity 290 and grating 300. This approach has the advantage of adding only one lithographic step to the fabrication sequence, and it may be the same lithographic step used to define the lateral waveguide, as described in FIG. 5.

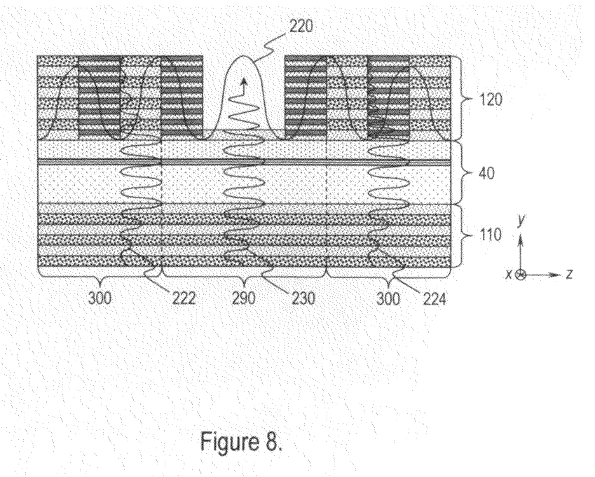

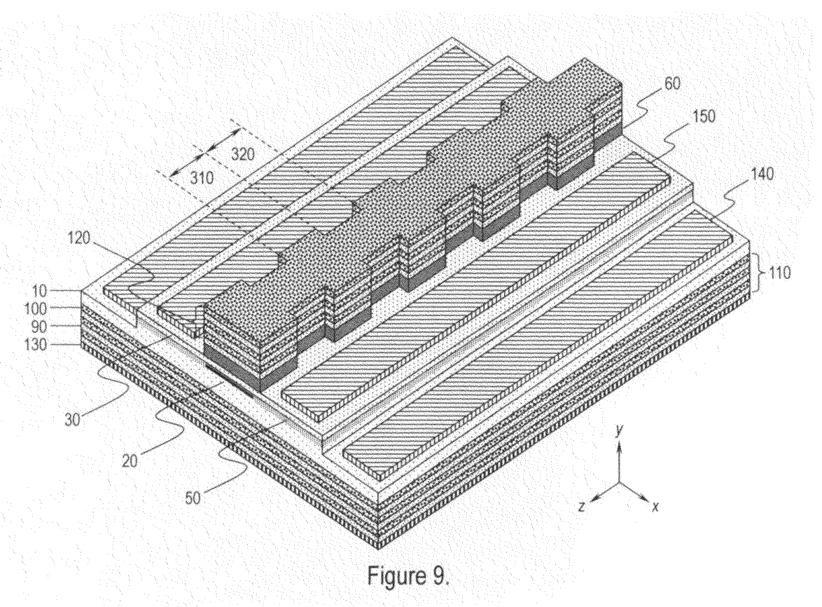

In an alternative embodiment, shown in FIG. 8, index modulation is implemented in the longitudinal direction via alternating evanescent and DBR cladding on at least one side of the active area. In this example, a bottom DBR 110 forms the lower cladding along the longitudinal axis. On the top, however, the cladding comprises alternating sections of dielectric DBR 122 and air. In the top DBR sections, the vertical mode 222 is a standing wave with an exponentially decaying envelope function. The vertical mode of the air section 224 comprises a standing wave in the bottom DBR and an evanescent wave in the air. A longitudinally propagating plane wave 220 then sees periodic regions of high (DBR) and low (evanescent) index which act as a mirror. With sufficient reflectivity, this feedback can reduce the longitudinal threshold such that the lowest overall threshold will belong to a mode with a k-vector that is significantly off the vertical axis. In fact, this wave must be totally internally reflected at the cavity/air interface for an evanescent wave to exist. For a cavity terminating in a semiconductor of index 3.4, this angle is 17°. The height of the dielectric DBR is determined by the quarter wave thicknesses of the dielectric pair and the number of pairs required to achieve sufficient reflectivity (e.g. >99.9%). The decay constant of the air evanescent wave and the exponentially decaying envelope function of the DBR standing wave are preferably made similar, such that the energy transfers longitudinally without much scattering loss. In addition, the width of the DBR and air evanescent regions must be scaled according to their effective indexes. For example, if the effective index of the dielectric DBR is 1.8, then the ratio of the DBR to evanescent widths will be 1/1.8=0.55, for a given longitudinal wavelength. Note that the longitudinal cavity 290 comprises air in the upper mirror 120. An output coupler may be formed in the cavity by removing all of the mirror pairs leaving only a partial cavity with a leaky vertical mode 230 (cavity modulation).

In an alternative embodiment, shown in [0015] FIG. 8, index modulation is implemented in the longitudinal direction via alternating semiconductor (high index section) 124 and dielectric (low index section) 122 DBRs on at least one side of the active area. In this embodiment, periodic sections of the semiconductor mirror are removed and replaced by a dielectric DBR 124 with the appropriate contrast and number of mirror pairs required to achieve sufficient reflectivity (e.g. >99.9%). Alternatively, a hybrid mirror comprising a partial semiconductor and a partial dielectric mirror may be used in the high index section. Alternatively, an all dielectric mirror comprising additional spacer layers may be used in the high or low index sections to provide index contrast. For all variations on this embodiment in each section 122, 124 the vertical mode is a standing wave with an exponentially decaying envelope function 222, 224. Note that the longitudinal cavity 290 is of a hybrid nature, comprising an inner dielectric section of ½-Λ flanked by two ¼-wave semiconductor DBRs. This implementation allows the formation an output coupler in the center 1/2-Λ of the cavity by reducing the number of mirror pairs (mirror modulation) in the dielectric mirror of this region. In the example of [0015] FIG. 8 all of the mirror pairs have been removed leaving only a partial cavity with a high transmission loss out the top 230. In this way a single spatial lobe of the longitudinal standing wave may be selected for output.

It is possible to reduce the amount of pumping required to achieve threshold by rendering some of the gain material in the longitudinal path transparent. This can be done by etching and regrowth of the active layers or by quantum well mixing as described in the discussion of output coupling below. In this way, the threshold of the laser and the mode control become decoupled and can be optimized independently.

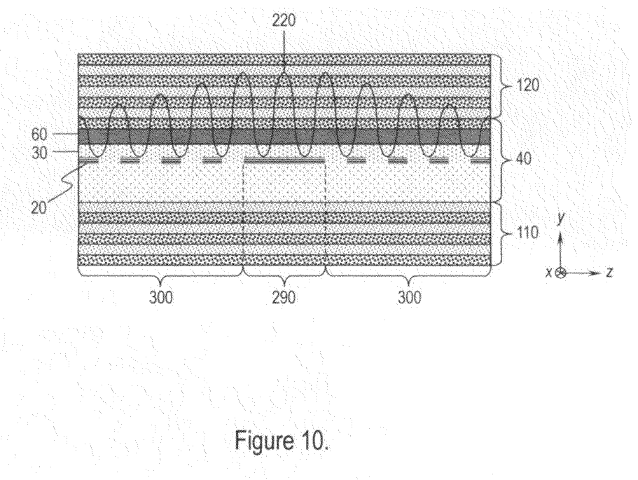

In an alternative embodiment the width of the waveguide can be varied along the z-axis. This may be achieved by varying the width of the ridge, as depicted in FIG. 10. The bottom mirror layers 80, 90, 120 and semiconductor layers 10, 20, 30 are uniform, as defined in FIG. 1. The dielectric layers of the hybrid cavity 60, 70 and upper mirror layers 120 have varying width with alternating wide 310 and narrow 320 sections of ¼-Λ in length. If the lateral optical mode extends to the air/semiconductor interface, feedback is provided by partial reflection of the optical mode by this interface and large feedback coefficients may be achieved. This approach can also provide optical scattering out of the side of the waveguide, thereby providing loss modulation as well as index modulation. Ordinarily an increase in loss is detrimental to the performance of an optoelectronic device. However, in the case of an LED, if the scattered light is absorbed by a light emitting phosphor, then this is considered useful light output and no drop in efficiency will occur. Advantageously, this approach adds no steps to the fabrication sequence.

Alternatively, if the optical mode does not extend to the air/semiconductor interface, index contrast is provided by an effective index difference between wide and narrow sections of the waveguide. Using the example from Equation 4, if the width of the waveguide is varied from 10 to 5 um, the wavelength difference between sections would be approximately 0.2 nm. According to Equation 1 this would provide an effective index difference of approximately 0.0012, requiring a large number of reflections to achieve the necessary feedback and quality factor. As a result, it is difficult to achieve high contrast purely through the use of effective index modulation via a variation in waveguide width.

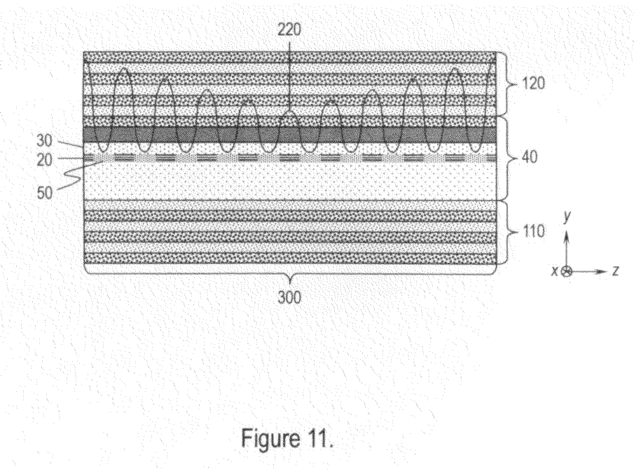

In an alternative approach, gain or loss modulation is used to provide wavelength selectivity. We now provide two examples of each. In an exemplary embodiment, shown in FIG. 11, gain modulation is achieved by etching the MQW active area with the period of the longitudinal grating. Referring to FIG. 11, a cavity 290 flanked on either side by a grating 300 is etched directly into the active layers 20 of the device. Typically an epitaxial layer 30 is regrown on top of the grating to provide uniform current injection, separate carrier confinement, vertical optical confinement, and/or reduced surface recombination. From the regrown layer 30 current is injected both vertically and laterally into the quantum wells. The optical gain of the pumped quantum wells is periodic, thereby providing gain preferentially to a single longitudinal mode 220. Note that some index modulation is concomitant in this approach. Advantageously, this method reduces the required current injection for a given optical output by reducing the amount of active area that is electrically pumped.

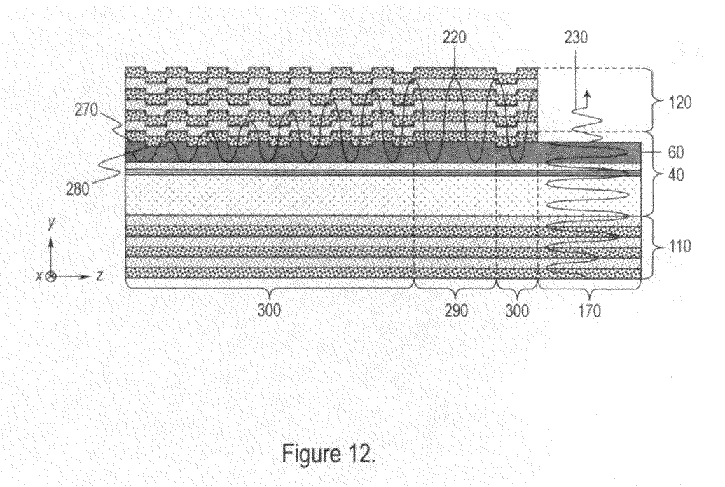

In an exemplary embodiment, depicted in FIG. 12, gain modulation is achieved by forming a blocking implant 50 with the period of the longitudinal grating. The implant is centered vertically on the MQW active area and locally increases the material resistance forcing the current into adjacent, unimplanted areas. The antinodes of the optical standing wave 220 appear where there is optical gain, while the nodes reside in the unpumped (blocked) regions 50. Under high current injection conditions the uninjected material absorbs sufficient photons to become transparent, at which point the total optical loss decreases. However, injection of the current at the antinodes still provides relatively more gain than is present at the nodes, thereby providing gain preferentially to a single longitudinal mode 220. Advantageously, this method reduces the required current injection for a given optical output by reducing the amount of active area that is electrically pumped.

In an exemplary embodiment, loss modulation is achieved by changing the reflectivity of the upper mirror with the period of the longitudinal grating. The reflectivity of the upper mirror may be reduced by a small amount, as for example by removing the metal mirror or one or more dielectric mirror pairs at the nodes of the longitudinal standing wave. The reflectivity of the upper mirror may be reduced by a large amount, as for example by phasing the dielectric mirror such that it is antireflective at the nodes of the longitudinal standing wave. Advantageously, the light scattered out of such a periodically modulated upper mirror would provide useful optical output for the efficient operation of an LED.

In an exemplary embodiment, loss modulation may be achieved by formation of periodically modulated waveguide sidewalls, similar to the device described in FIG. 10. In this embodiment, however, the first dielectric layer 60 has a uniform width, while the second dielectric layer 70 and upper mirror layers 120 would vary smoothly and periodically in width. In the wide sections the waveguide simply conducts the wave along the z-axis, whereas in the narrow sections the lateral mode confinement factor is reduced. The evanescent portion of the mode sees the first dielectric layer 60 which acts as an AR coating efficiently coupling light vertically out of the waveguide. This represents periodic loss thereby promoting longitudinal mode selectivity. Alternatively, instead of wide and narrow sections, the waveguide sidewalls could be made smooth and rough. The rough sections, formed, for example, by a serrated edge, provide lateral scattering out of the waveguide and would therefore be lossier. The smooth and rough sections correspond to the antinodes and nodes of the longitudinal standing wave, respectively. The lowest order longitudinal mode experiences the lowest loss, while higher order modes experience higher loss due to scattering out of the waveguide. Advantageously, this method requires no additional fabrication steps.

With optical feedback present in all three dimensions and sufficient electrical pumping, the gain of the quantum wells is forced to feed a narrow band of wavelengths centered on the cavity wavelength. However, both the gain peak and cavity wavelengths shift with increasing temperature and bias current, albeit at different rates and possibly different directions, due to thermally-induced index changes and carrier-induced band filling, respectively. For GaAs and InP based devices, the quantum well gain will shift toward longer wavelengths at a faster rate than the cavity wavelength. On the other hand, GaN-based quantum wells have exhibited a blue shift with increasing current. For maximum output power, the peak gain and cavity wavelengths should line up at the intended operating point (current and temperature). Thus, the cavity wavelength may be detuned from the gain peak at room temperature and zero bias. The amount and direction of the optimum detuning depends on the direction and relative rate of change between the gain peak and cavity wavelengths, as is known in the art.

An important element of the present invention is the optical output coupler. Referring again to FIG. 1, when longitudinal feedback is not present spontaneous emission is amplified as it travels down the waveguide 160, as in a SLED, growing in intensity until it reaches the end of the waveguide. As a result, the greatest amount of light can be extracted from the ends of the waveguide. To efficiently extract the light, the phase of the top mirror, as seen from the active area, is changed from reflecting to antireflecting (mirror modulation). Referring again to FIG. 2, in an exemplary embodiment, the top mirror 120 and part of the cavity 70 are removed (cavity modulation) in the output section 170 such that the remaining partial cavity sees a high reflectivity toward the bottom mirror 110 and low reflectivity toward the top. The vertically travelling light 220 is efficiently coupled out of the cavity 230 as it travels simultaneously in the longitudinal direction. The light can be conceptualized as zigzagging up and down as it progresses along the z-axis. Once it reaches the partial cavity, only a few vertical passes are required to couple out almost all of the light. To reduce reflections from the top mirror/air interface back into the waveguide, the mirror is tapered laterally to a point (FIG. 1, 180). The length of the taper depends on the maximum allowable reflectivity for feedback to the waveguide. In a typical SLED device, for example, the maximum reflectivity is approximately 10⁻⁴. In general, longer tapers provide lower reflectivity. In an alternative embodiment, the taper may be achieved vertically by successive removal of mirror layers. This process requires additional photolithography and etching steps and is therefore significantly more complex.

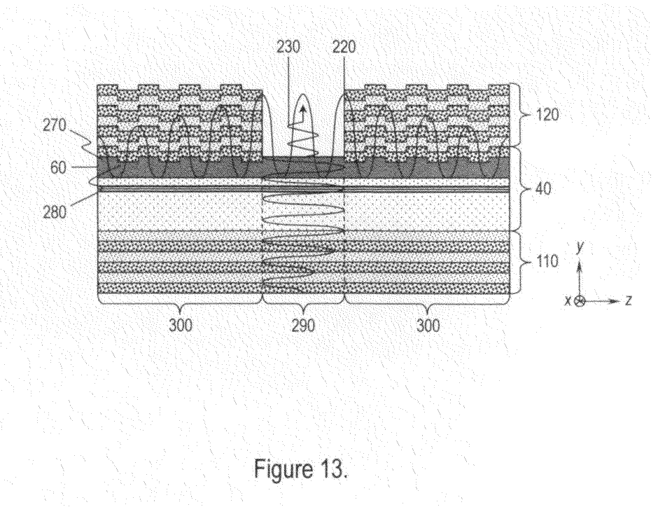

In the presence of longitudinal feedback, the peak intensity of the optical wave occurs at the position of the 1-Λ cavity. In this case, there are several choices for efficient extraction of the light, such as for example, an asymmetric longitudinal cavity with an abrupt output coupler, or an intra-longitudinal cavity output coupler. In a first embodiment, exemplified in FIG. 13, the longitudinal cavity 290 is placed near one end of the waveguide 300 thereby shifting the peak optical intensity 220 toward the output coupler 170. The length and coupling coefficient of the grating are chosen such that at the other end of the waveguide the light intensity is negligible. In this embodiment the waveguide is terminated abruptly, and the waveguide/air interface provides significant feedback for wavelength selectivity. If less reflectivity is desired, the interface can be moved toward a null in the longitudinal standing wave 220.

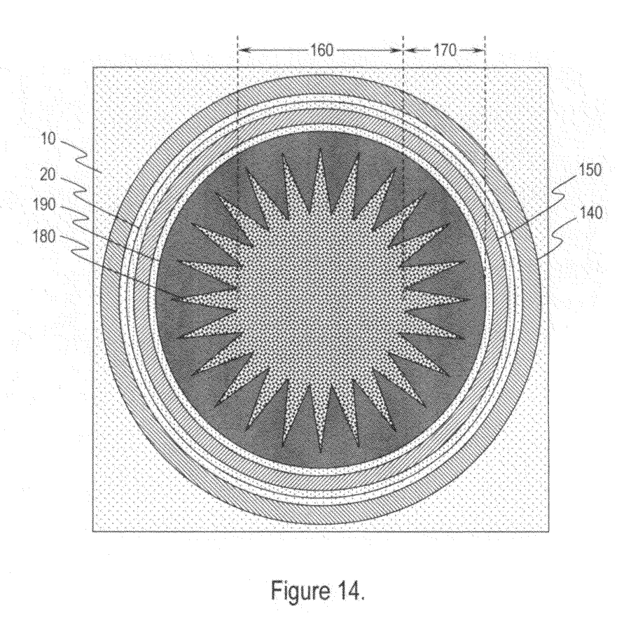

In a second embodiment, exemplified in FIG. 14, the longitudinal cavity 290 is placed in the center of the waveguide 300 coincident with the peak light intensity 220. The top mirror 120 and part of the cavity 40 are removed over the longitudinal cavity such that the remaining partial cavity sees a high reflectivity toward the bottom mirror 110 and low reflectivity toward the top, thereby forming an output coupler. For the most efficient coupling into the longitudinal cavity the upper mirror is terminated at the intracavity nulls of the longitudinal standing wave 220. However, extending the cavity 290 to 1-Λ and terminating it at the peaks of the standing wave, as depicted in the Figure, increase the Q of the cavity and can reduce the required length of the longitudinal grating, or the contrast of high 270 and low 280 index sections. The length and coupling coefficient of the longitudinal grating are chosen such that at the opposite ends of the waveguide the light intensity 220 is negligible. Alternatively, the ends of the waveguide may be coupled to adjacent emitters and the unextracted light thereby recycled.

The output section(s) of the ROCSLED may be pumped or unpumped. If pumped, the output section(s) provide additional gain for the longitudinal travelling wave. If unpumped, the quantum wells of the active area will be absorbing and must be bleached before becoming optically transparent. This may lead to lower output efficiency of the device. One method for reducing the loss in unpumped quantum wells is vacancy or impurity-induced quantum well disordering. Using these techniques band shifts of several tens of nm have been observed by various groups in other materials systems [7,8,9]. For example, In the InGaN/GaN system it is believed that annealing of undoped quantum wells causes diffusion of indium atoms via Ga vacancies in the GaN barrier region. In an exemplary embodiment, the quantum wells in the output section of the device are implanted or impurity-diffused resulting in a smearing of the well/barrier interfaces. The energy profile of the quantum wells goes from square to smooth (such as an error-function type profile) and the energy level within the well rises. As the transition energy between electron and hole functions increases, the absorption band moves to higher energies (shorter wavelengths). As a result, the waveguide becomes transparent to the primary emission wavelength. Such a transparent output coupler may contribute to the optimum efficiency of the device.

If required, additional steps may be taken to enhance the extraction efficiency of the output coupler. Examples include a photonic crystal [10,11], plasmonic grating [12], surface roughening [2,13], or subwavelength grating [14]. Such measures would only be warranted if the enhancement in extraction efficiency outweighed the additional cost of implementation.

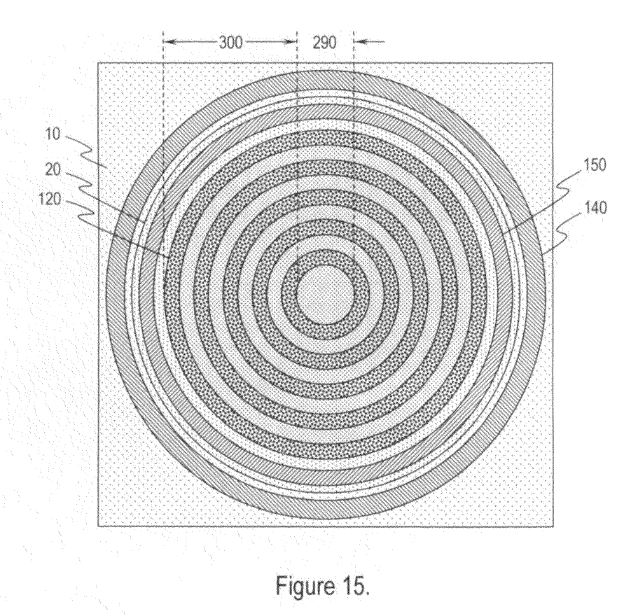

Other shapes for the gain and output sections of the device are also possible and the embodiments presented here are merely suggestive and neither preferred nor exhaustive. In an alternative embodiment without longitudinal feedback, illustrated in FIG. 15 a circular gain section 160 may be terminated in a circular output coupler 170. The output coupler comprises multiple, tapered mirror sections 180 resembling a starburst pattern, themselves terminating in a leaky cavity ring 190. Ring contacts 140, 150 for n− 10 and p-type 20 materials surround the leaky cavity section 190.

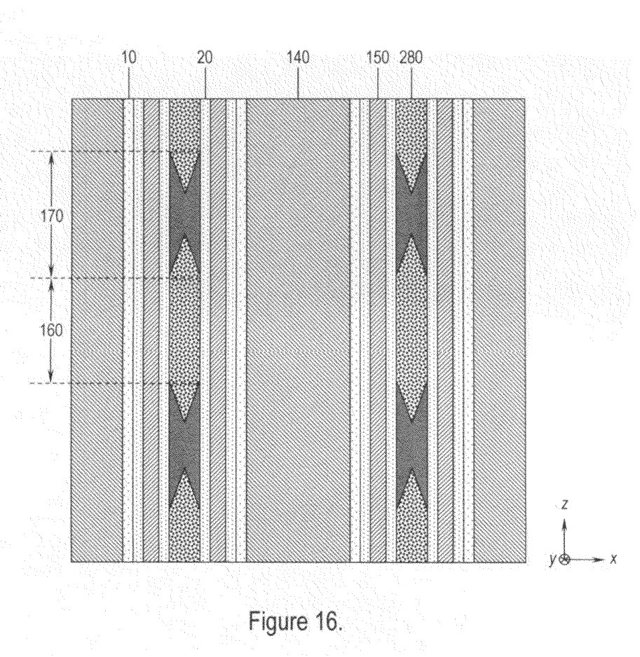

In an alternative embodiment with longitudinal feedback, illustrated in FIG. 16, a circular gain section 300 surrounds a circular cavity/output coupler 290 (center). In the Figure, the top mirror 120 is index modulated to provide feedback in the radial direction. An equivalent cross section along the diameter of this device is shown in [0015] FIG. 8. Ring contacts 140, 150 for n− 10 and p-type 20 materials surround the grating section 300. In a variation on this embodiment the cavity is moved to a ring at some distance from the center, with mirror modulation used to form a spatially concurrent optical tap. Such a device will lase in a radial pattern and have near field output beam that is annular in shape. Such an annular output could be used to efficiently couple the light to the cladding mode of an optical fiber. Other shapes, such as triangles or squares may also be used, subject to appropriate output coupler design. These and other embodiments will be readily apparent to those skilled in the art, and the generic principles defined herein can be applied to other embodiments without departing from the spirit or scope of the invention.

Simplicity of fabrication is key to high yields and low cost for any optoelectronic device. In an exemplary embodiment, the ROCSLED may be formed using standard semiconductor planar processes. Referring to FIG. 1, the epitaxial layers of the diode 10, 20, 30 are disposed on a substrate. The substrate can be one of a single crystal of sapphire, Si, GaN or any other material and/or crystal orientation suitable for the high quality growth of the desired layers at the desired emission wavelength. The epitaxial layers comprise a bottom partial cavity 10, a MQW active area 20, and a top partial cavity 30. In the present embodiment the bottom and top partial cavities comprise n- and p-type GaN, respectively. The MQW active area comprises one or more InGaN quantum wells surrounded by GaN barriers. The active area may be doped, undoped, modulation doped, delta-doped or any combination thereof. Advantageously, the ROCSLED structure allows the order of the layers to be reversed. For example, the bottom and top partial cavities may comprise p- and n-type GaN, respectively. Such a configuration could improve contact to the p-layer if a blocking implant is required. This is because the implant penetrates the entire top partial cavity, causing damage and poor contact resistance, but has only shallow penetration into the bottom cavity. This shallow implant damage may be removed during the mesa etch for the bottom intra-cavity contact yielding low contact resistance.

In an exemplary embodiment, the fabrication of the ROCSLED begins with a transfer of the epitaxial layers from the host to a surrogate substrate, typically copper Cu or Si. First, a 100 nm SiNₓ protection layer is disposed on the GaN epitaxy, followed by 0.5 μm of polycrystalline Si (poly-Si). Next, an adhesive, such as epoxy, is used to temporarily bond the sapphire substrate to a handle wafer, typically a Si wafer. Laser liftoff [15] or sacrificial layer undercutting may be used to remove the host sapphire substrate. The exposed backside of the epitaxy is then cleaned and prepared for bottom mirror deposition. In the present embodiment, four pairs of dielectric mirror 110 are disposed on the bottom partial cavity, each pair comprising ¼-λ of SiO₂ 100 and ¼-λ of TiO₂ 90. A final mirror layer 130 comprising a metal, such as Au or Ag, is disposed on the dielectric mirror. Advantageously, this final mirror layer may be used to facilitate wafer bonding of the ROCSLED structure to the surrogate substrate. If high-temperature processing is used after the bonding step, the metal layer may be omitted and a fusion bond used instead. In an alternative embodiment, the bottom mirror comprises a metal layer only. This design has the advantage of simplified processing and better thermal conductivity. Bonding is achieved by placing the surrogate and handle wafers into intimate contact and adding pressure and temperature for a certain length of time. The handle wafer is removed by suitable means, such as etching of the substrate and/or dissolution of the adhesive. Next, the protection layers are removed by suitable means, such as plasma (dry) or wet chemical etching. The structure is then ready for topside processing.

The vertical optical cavity is completed by disposing a pair of dielectric layers on the semiconductor partial cavity. In the present embodiment, the semiconductor partial cavity has an optical length of 1¼-λ. First, a ½-λ layer of SiNₓ 60 is disposed on the partial cavity. This layer, which is deposited everywhere, extends the optical cavity and forms an antireflection coating thereon. The top cavity is completed during the deposition of the top mirror as follows: first, the wafer is patterned with the shape of the waveguide and output couplers using photolithography techniques as are known in the art. Next, a ¼-λ layer of TiO₂ 70 is disposed on the partial cavity. This layer completes the 2-λ cavity 40 and is followed by the disposition of several pairs of dielectric mirror 120, each pair comprising ¼-λ of SiO₂ 100 and ¼-λ of TiO₂ 90. The dielectric layers are deposited using a low-temperature process such as sputtering, evaporation, or ion-beam assisted deposition, as is known in the art. Completion of the mirror layer deposition is achieved via photoresist liftoff.

In an exemplary embodiment, current flow is directed through the use of a blocking implant 50. After disposition of the partial cavity and mirror layers in the shape of the waveguide 160 and output couplers 170, the structure is proton implanted to the depth of the quantum wells. The implant is masked in a self-aligned fashion by the waveguide, with additional masking provided by photoresist, if necessary. Typically such an implant is annealed at high temperature to heal the crystal above the implant, in this case the p-type cavity, so as to improve its electrical properties. Once the implant/(anneal) is complete, a high resistivity layer will exist under the p-contact layer forcing the current to move laterally underneath the waveguide, thereby providing for uniform current injection. Advantageously, the same implant/anneal process may be used to induce disordering of the quantum wells, as previously mentioned, thereby rendering the unpumped quantum wells transparent. In an alternative embodiment, the structure is implanted with oxygen ions instead of protons. During the anneal process the oxygen forms oxides with the constituent elements of the active area, thereby forming an oxide current aperture and optical waveguide.

Up to this point in the fabrication, no etching has occurred. In an exemplary embodiment, the anti-reflection layer 60 is patterned at the output couplers, typically in a waveguide or fanout shape. During the same etch step the SiNₓ is removed from either side of the waveguide in a sell-aligned fashion using the mirror layers 120 as a mask. The top intra-cavity contact is then disposed such that it makes contact to the top partial cavity on either side of and over the top of the waveguide, as depicted in FIG. 3. Next, the output couplers are protected and a mesa is etched through the top partial cavity 30, below the quantum wells 20 and into the bottom partial cavity 10. Advantageously, the top contact metal 150 may be used as a self-aligned mask for this etch. A highly doped layer within the bottom partial cavity may be used to improve contact resistance of the bottom contact. In this case, the etch is controlled so as to stop within this highly doped layer. An inter-contact dielectric 80 is deposited everywhere except over the output sections of the device. Vias are opened within the bottom contact area, and the bottom contact metal 140 is disposed everywhere except over the output couplers. Thus, n- and p-type contacts are coincident everywhere but over the output couplers and at the edges of the chip where separate bond pads are exposed. This is the same for designs with or without longitudinal feedback. The contacts are annealed, if necessary, to provide low-resistance Ohmic contacts.

The device is now operational. If longitudinal feedback is desired, as discussed previously, the necessary process steps are generally included in the exemplary embodiment presented here, requiring only changes in the photolithography masking patterns and perhaps an additional etch or liftoff step to pattern the feedback layer. The above fabrication method is one of several variations that may be used to produce a ROCSLED and is given by way of example only. Other variations will be readily apparent to one skilled in the art and fall within the scope of this specification.

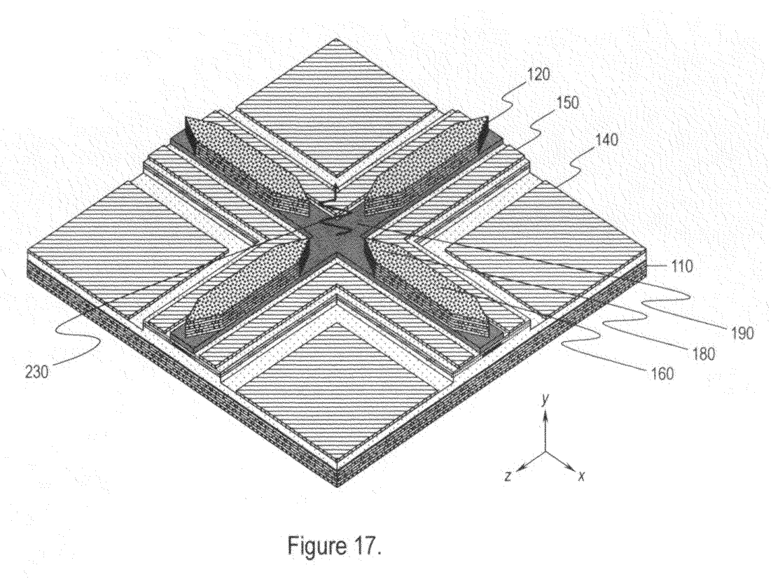

The ROCSLED described above may be fabricated as an isolated device. However, one great advantage of the proposed device is that it may be ganged together in one- or two-dimensional arrays. FIG. 17 depicts a ROCSLED chip with several one-dimensional arrays. In each linear array, waveguides 160 are linked together with common output couplers 170. In an alternative embodiment, n− 140 and p− 150 type contacts may be placed on opposite sides of the waveguide for unidirectional current flow across the waveguide, which may reduce current crowding.

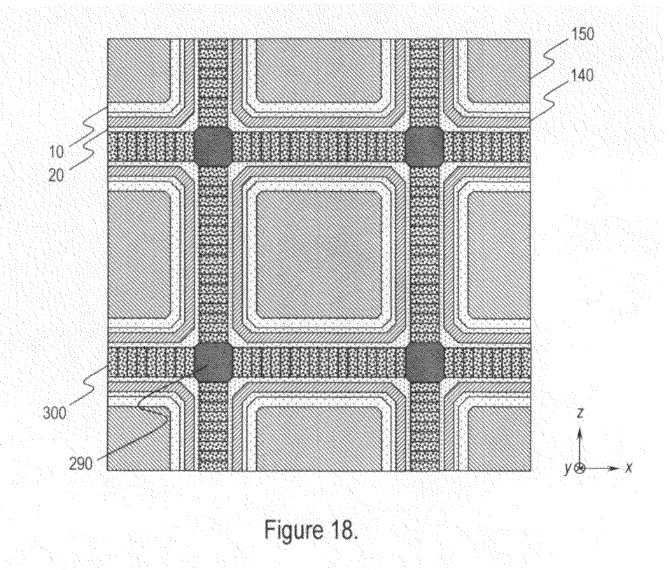

In an exemplary embodiment, the emitters may be arranged in a two-dimensional array, as illustrated in FIG. 18. The waveguides 160 are placed such that four devices feed a common output coupler 180, 190. Advantageously, the common output coupler design allows photons that are not emitted to remain in the waveguide and be recycled in the adjacent ROCSLED. In the Figure n− 140 and p− 150 type contacts have been minimized for clarity. However, because light exits the device 230 only at the output coupler, which is a small fraction of the area of the ROCSLED chip, metal may be placed over all other areas of the device without penalty. A cross section of a fully metalized waveguide is given in FIG. 3. Thus, with appropriate isolation, large area metal layers may be used to make contact to the arrayed devices. This simplifies the fabrication and may help to conduct heat away from the active areas. In an exemplary embodiment, an additional via is etched between emitters all the way to the substrate/heat sink. A thick metal layer, such as electroplated Au, is disposed atop the bottom contact 140 allowing heat from the top and sides of the device to propagate through a low thermal resistance path to the heat sink.

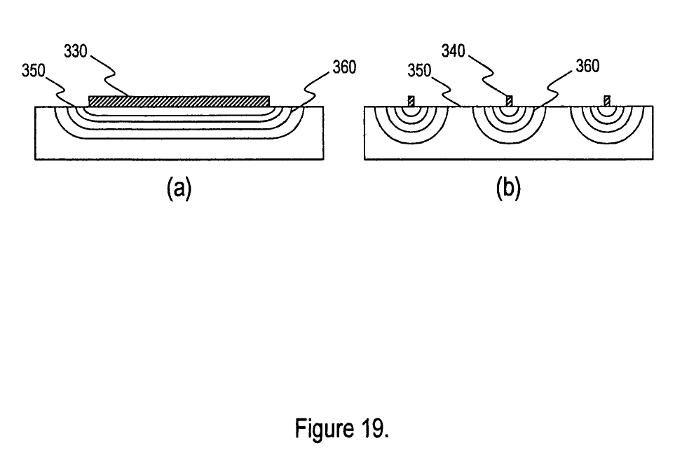

An exemplary embodiment of a two-dimensional ROCSLED chip with longitudinal feedback is presented schematically in FIG. 19. Four waveguides 300 feed into a single, common cavity/output coupler 290. The n− 10 and p− 30 type layers are exposed in the wells between devices. Pad 150 and ring 140 contacts are made to the n- and p-type materials, respectively. As in the previous example, because light exits the device only at the output coupler 290, with appropriate isolation layers metal may be placed over all other areas of the device without penalty.

In an exemplary LED embodiment, the width of the waveguide is 5 μm and the length is 100 μm. Therefore, many ROCSLED emitters may be placed within a chip of a given size, say 1×1 mm². The lack of cleaved or etched facets greatly simplifies the fabrication of the ROCSLED and allows the integration of dense 2-D arrays. For example, for a ROCSLED area of 500 μm² and an array of 200 emitters, the electrically pumped area is 0.1 mm², or 10% of the chip area. Advantageously, the spontaneous emission spectrum narrows with increasing current injection thereby making the output coupling more efficient. Another advantage is that it is easier to make current injection uniform over the area of a single emitter than over the area of the entire chip. As a result, the ROCSLED is inherently scalable to much larger areas than a typical HBLED, potentially reducing the number of LED packages required for a given light output.

Heat is a major concern in the design and operation of LEDs and lasers. As the temperature of the active area increases the internal quantum efficiency drops causing the external efficiency to reach a maximum and then decline with further current injection. A significant advantage of the ROCSLED structure as applied to LEDs is that the active area in the shape of a waveguide can be made small enough to approximate a line source. This allows heat to flow in two dimensions, vertically and laterally. The benefits of planar versus line heat sources can be more easily understood with the help of FIG. 20. FIG. 20(a) shows the isotherm profile 360 for a large area source 330 on a larger heat sink 350. For a homogeneous heat sink the heat flow under the chip is primarily one dimensional. FIG. 20(b) shows the isotherm profile for a series of line sources 340 on a homogeneous heat sink 350. The isotherms 360 are cylindrical and spaced farther apart indicating more efficient cooling. In an exemplary embodiment these line sources, representing the individual ROCSLED waveguide elements, are spaced far enough apart to avoid thermal crosstalk. As a result, the junction temperature of each ROCSLED element remains low. Additionally, the bottom mirror could be made of metal only, further simplifying the process and improving thermal heat sinking.

### ALTERNATIVE EMBODIMENTS

The previous description of the disclosed embodiments is provided to enable any person skilled in the art to make or use the present invention. Various modifications to these embodiments will be readily apparent to those skilled in the art, and the generic principles defined herein can be applied to other embodiments without departing from the spirit or scope of the invention. For example, the present invention can be practiced with any of a variety of Group III-V or Group II-VI material systems that are designed to emit at any of a variety of wavelengths. It is therefore desired that the present embodiments be considered in all respects as illustrative and not restrictive, reference being made to the appended claims as well as the foregoing descriptions to indicate the scope of the invention.

### REFERENCES

1. R. Windisch, R. Butendeich, S. Illek, S. Kugler, R. Wirth, H. Zull, and K. Streubel, “100-Im/W InGaAIP thin-film light-emitting diodes with buried microreflectors,” IEEE Photon. Tech. Lett., vol. 19, no. 10, pp. 774-776, 2007.
2. T. Fuji, Y. Gao, R. Sharma, E. L. Hu, and S. Nakamura, “Increase in the extraction efficiency of GaN-based light-emitting diodes via surface roughening,” Appl. Phys. Lett., vol. 84, pp. 855-857, 2004.
3. H. Benisty, H. D. Neve, and C. Weisbuch, “Impact of planar microcavity effects on light extraction—Part II: Selected exact simulations and role of photon recycling,” IEEE J. Quantum Electron., vol. 34, no. 9, pp. 1632-1643, 1998.
4. G. Björk, S. Machida, Y. Yamamoto, and K. Igeta, “Modification of spontaneous emission rate in planar dielectric microcavity structures,” Phys. Rev. A., Gen. Phys., vol. 44, pp. 669-681, 1991.
5. G. R. Hadley, “Effective Index Model for Vertical-Cavity Surface-Emitting Lasers,” Opt. Lett., vol. 20, pp. 1483-1485, 1995.
6. H. Ng, T. Moustakas, S. Chu, “High Reflectivity and Bandwidth AlN/GaN Distributed Bragg Reflectors Grown by Molecular Beam Epitaxy,” Appl. Phys. Lett., vol. 76, pp. 2818-2820, 2000.
7. D. Sengupta, V. Jandhyala, K. Sangsig, F. Weich, J. Malin, P. Apostolakis, K. C. Hseih, Y. C. Chang, S. L. Chuang, S. Bandara, S. Gunapala, M. Feng, E. Michielssen, and G. Stillman, “Redshifting and Broadening of Quantum-Well Infrared Photodetector's Response via Impurity-Free Vacancy Disordering,” IEEE J. Sel. Topics in Quant. Electron., vol. 4, no. 4, 1998.
8. J. J. Coleman, P. D. Dapkus, C. G. Kirkpatrick, M. D. Camras, and N. Holonyak, “Disorder of an AlAs—GaAs Superlattice by Silicon Implantation,” Appl. Phys. Lett., vol. 40, p. 904, 1982.
9. H. H. Tan, J. S. Williams, C. Jagadish, P. T. Burke, and M. Gal, “Large Energy Shifts in GaAs—AlGaAs Quantum Wells by Proton Irradiation Induced Intermixing,” Appl. Phys. Lett., vol. 68, p. 2401, 1996.
10. C. H. Lin, H. H. Yen, D. F. Lai, H. W. Huang, C. H Chao, H. C. Kuo, T. C. Lu, S. C. Wang, and K. M. Leung, “Enhanced Vertical Extraction Efficiency From a Thin-Film InGaN—GaN Light-Emitting Diode Using a 2-D Photonic Crystal and an Omnidirectional Reflector,” IEEE Photon. Tech. Lett., vol. 20, no. 10, pp. 836-838.
11. F. S. Diana, A. David, I. Meinel, R. Sharma, C. Weisbuch, S. Nakamura, and P. M. Petroff. “Photonic Crystal-Assisted Light Extraction from a Colloidal Quantum Dot/GaN Hybrid Structure,” Nanoletters, vol. 6, no. 6, pp. 1116-1120, 2006.
12. J. Vutkovic, M. LoTar, O. Painter, and A. Scherer, “Surface plasmon enhanced LED,” QELS Conference, Anaheim, Calif., Paper JMB3 (Invited), pp. 41-42, 2000.
13. C.-E. Lee, Y.-C. Lee, H.-C. Kuo, T.-C. Lu, and S.-C. W., “Further Enhancement of Nitride-Based Near-Ultraviolet Vertical-Injection Light-Emitting Diodes by Adopting a Roughened Mesh Surface,” IEEE Photon. Tech. Lett., vol. 20, no. 10, pp. 803-805, 2008.
14. M. C. Y. Huang, Y. Thou, and C. J. Chang-Hasnain, “Single Mode High-Contrast Subwavelength Grating Vertical Cavity Surface Emitting Lasers,” Appl. Phys. Lett., vol. 92, no. 17, pp. 1108-1110.
15. W. S. Wong, T. Sands, N. W. Cheung, M. Kneissl, D. P. Bour, P. Mei, L. T. Romano, and N. M. Johnson, “Fabrication of Thin-Film InGaN Light-Emitting Diode Membranes by Laser Lift-off,” Appl. Phys. Lett., vol. 75, no. 10, pp. 1360-1362, 1999.

I claim:

1. A light emitting device comprising
a light generation section comprising
a pair of mirrors surrounding an optical cavity in the vertical (y) direction,
a waveguide in the lateral (x) direction, and
a traveling wave in the longitudinal (z) direction;
and a light output section comprising
a bottom mirror and
a means of providing a leaky mode emitting away from said mirror.

2. The light emitting device of claim 1 wherein said waveguide is formed by means of one or more of the following;
a variation in material index,
a variation in effective index, or
a thermally induced index variation.
The light emitting device of claim 1 wherein said means of providing a leaky mode comprises one of either
a partial optical cavity, or
an optical cavity and a top mirror, said combination having increased loss relative to said light generation section.

3. The light emitting device of claim 1 in which said waveguide is replaced by a light generation section of any shape that supports a travelling wave in the plane of said cavity.

4. The light emitting device of claim 1 wherein said pair of mirrors comprise dielectric material.

5. The light emitting device of claim 1 further comprising a form of feedback, such as a periodic variation in material index, effective index, gain or loss, in the longitudinal (z) direction, said feedback supporting a standing wave of at least half a wavelength in said direction.

6. The light emitting device of claims 1 and 5 in which said waveguide is replaced by said feedback in the radial (r) direction.

7. The light emitting device of claim 1 comprising one or two intracavity contacts formed from one or more of the following;
a semiconductor layer,
a transparent conductor, or
a thin metallic layer placed at an optical node in the vertical standing wave.

8. The light emitting device of claims 4, 5 and 7 in which said feedback supports a standing wave of less than half a wavelength in the longitudinal or radial (x or r) direction.

9. The light emitting device of claim 1 or claim 5 epitaxially transferred to a surrogate substrate.

10. A chip comprising a one or two dimensional array of light emitting devices as defined in claim 1 or claim 5.

11. The chip of claim 10 wherein said light emitting devices have common output sections.
